(19) United States
(12) Patent Application Publication
(10) Pub. No.: US 2010/0089440 A1
(43) Pub. Date: Apr. 15, 2010

(54) Dual Junction InGaP/GaAs Solar Cell

(75) Inventors: Allen L. Gray, Albuquerque, NM (US); Daniel Aiken, Cedar Crest, NM (US); Mark Stan, Albuquerque, NM (US); Paul Sharps, Albuquerque, NM (US)

Correspondence Address: EMCORE CORPORATION, 1600 EUBANK BLVD, S.E., ALBUQUERQUE, NM, 87123, US

(73) Assignee: Emcore Corporation, Albuquerque, NM (US)

(21) Appl. No.: 12/248,654

(22) Filed: Oct. 9, 2008

(51) Int. Cl. H01L 31/0264

(52) U.S. Cl. 136/255

(57) ABSTRACT

The present application is directed to a multi-terminal semiconductor solar cell. The solar cell may be dual junction solar cells comprising single junctions independently interconnected by a middle lateral conduction layer (MLCL). The solar cells may include a GaAs subcell, a GaInP subcell, and a MLCL disposed therebetween. In addition, the solar cells may include a plurality of terminals. One terminal may be operatively connected to the GaAs subcell, a second terminal may be operatively connected to the GaInP subcell and a third terminal may be operatively connected to the MLCL.

### GOVERNMENT RIGHTS STATEMENT

This invention was made with government support under Contract No. LOX497530 awarded by the Defense Advanced Research Projects Agency. The government has certain rights in the invention.

### FIELD OF THE INVENTION

The present invention relates to photovoltaic solar cells. In particular, dual junction InGaP/GaAs semiconductor solar cells are disclosed.

### BACKGROUND

Photovoltaic cells often comprise semiconductors that convert solar radiation into electrical energy. Such semiconductors are generally solid crystalline materials that have an energy band gap between the valence band and the conduction band. When light is absorbed by the semiconductor, electrons in the lower-energy valence band may be excited to the higher-energy conduction band. As an electron is excited into the higher-energy conduction band, it leaves behind an unoccupied position, or an electron hole. These free electrons and electron holes contribute to the conductivity of semiconductors.

In order for light to excite an electron into the conduction band, the light, or photon, must have sufficient energy to overcome the band gap. If the light does not have sufficient energy to overcome the band gap, then the energy is merely absorbed as heat. Likewise, if the light has an excess of energy needed to excite the electron into the conduction band, the excess energy is converted into heat. Thus, an individual semiconductor having only one band gap can only convert a portion of the solar spectrum into electricity. However, if more than one semiconductor is arranged in a multi-junction tandem arrangement where each semiconductor has a different band gap, a larger portion of the solar spectrum can be absorbed and converted into electricity.

In a multi-junction tandem arrangement, the first semiconductor layer typically has a higher-energy band gap while the second semiconductor layer typically has a lower-energy band gap. Thus, as light strikes the top of the first semiconductor layer, higher-energy photons are absorbed in the first semiconductor layer and provide sufficient energy to excite electrons into the conduction band. Lower-energy photons, which do not provide sufficient energy to excite electrons in the first semiconductor layer, pass through the first semiconductor layer and are absorbed into the second semiconductor layer. The lower-energy photons provide sufficient energy to electrons in the second layer to excite the electrons into the conduction band of the second semiconductor layer.

Typically, semiconductors comprise one or more p-n junctions, which create electron flow as light is absorbed within the cell. A p-n junction is formed when a negatively doped (n-type) semiconductor material, is placed in contact with a positively doped (p-type) semiconductor material. Electrons present in the conduction band of the n-type layer diffuse across the junction and recombine with electron holes in the p-type layer. The combining of electrons and holes at the junction creates a barrier that makes it increasingly difficult for additional electrons to diffuse into the p-layer. This results in an imbalance of charge on either side of the p-n junction and creates an electric field that promotes the flow of current.

Often multi-junction solar cells only have two terminals. In a two-terminal device, the generated current flows through each of the connected semiconductor layers and thus, the current in each layer is generally the same. However, using a three-terminal structure enables independent current collection from each layer in the tandem semiconductor stack without the need for current matching between each cell.

### SUMMARY

Multi-terminal InGaP/GaAs solar cells are disclosed. The solar cell may include a GaAs first layer operatively connected with a first terminal. The GaAs first layer may have a band gap of approximately 1.43 eV. An InGaP second layer may be operatively connected with a second terminal and may have a band gap of approximately 1.84 eV. A middle lateral conduction layer may be disposed between the GaAs first layer and the InGaP second layer and may have a band gap higher than the band gap of the GaAs first layer.

In another embodiment, the solar cell may include a GaAs heterojunction subcell operatively connected with a first terminal. The GaAs bottom heterojunction subcell may have a band gap of approximately 1.43 eV. An InGaP homojunction subcell may be operatively connected with a second terminal and may have a band gap of approximately 1.84 eV. An InGaP middle lateral conduction layer may be disposed between the GaAs subcell and the InGaP subcell and may have a band gap of 1.93 eV and a sheet resistance of less than 10 ohm/sq. The InGaP middle lateral conduction layer may be operatively connected to a third terminal.

Another embodiment includes a photovoltaic solar cell arrangement. The arrangement may include an InGaN solar cell for converting photons having an energy between approximately 2.4 eV and approximately 2.6 eV into electric energy. In addition the arrangement may include a three terminal solar cell for receiving photons passing through the InGaN solar cell and converting photons having an energy of between approximately 1.84 eV and approximately 1.43 eV into electric energy. The three-terminal solar cell may include an InGaP layer associated with a first terminal. The InGaP layer may have a band gap of approximately 1.84 eV. An InGaP lateral conduction layer may be disposed below the InGaP layer and may have a band gap of 1.93 eV and a sheet resistance of less than 10 ohm/sq. The InGaP lateral conduction layer may be associated with a second terminal. A GaAs layer may be disposed below the InGaP lateral conduction layer and may have a band gap of approximately 1.43 eV. The GaAs layer may be associated with a third terminal.

In another embodiment a photovoltaic solar cell arrangement may include a first solar cell for converting light energy into electrical energy, and a prism for receiving the light energy passing through the first solar cell. The prism may be positioned to direct some of the light energy in a first direction toward a second solar cell and to direct some of the light energy in a second direction, generally orthogonal to the first direction, toward a third solar cell. Each of the second and third solar cells may be configured to convert the light energy into electrical energy. The second solar cell may include a first InGaP layer, a second InGaP layer disposed below the first InGaP layer, and a GaAs layer disposed below the second InGaP layer.

These and other features of the present teachings are set forth herein. Other features and advantages will become apparent to the one skilled in the art from the following drawings and description of various embodiments.

### BRIEF DESCRIPTION OF THE DRAWINGS

The skilled person will understand that the drawings described below, are for illustration purposes only. The drawings are not intended to limit the scope of the present teachings in any way.

FIG. 1 is a block diagram illustrating a solar cell having a first subcell, a second subcell, and a middle lateral conduction layer.

FIG. 2 is a schematic diagram of a hybrid optical concentrating system utilizing a first InGaN solar cell and a second solar cell having an InGaP subcell, a GaAs subcell and a middle lateral conduction layer.

FIG. 3 is a chart illustrating the quantum efficiency of a two-terminal solar cell as compared to the quantum efficiency of the individual cells within the three-terminal solar cell for a 10 mm×10 mm active area.

### DETAILED DESCRIPTION

The present invention relates to multi-terminal semiconductor solar cells. The solar cells may be dual junction solar cells comprising single junctions independently interconnected by a middle lateral conduction layer (MLCL). The solar cells include a GaAs subcell 12, InGaP subcell 10, and a MLCL 14 disposed therebetween. In addition, the solar cells may include a plurality of terminals. A first terminal 18 may be operatively connected to the GaAs subcell 12, a second terminal 16 may be operatively connected to the InGaP subcell 10 and a third terminal 20 may be operatively connected to the MLCL 14.

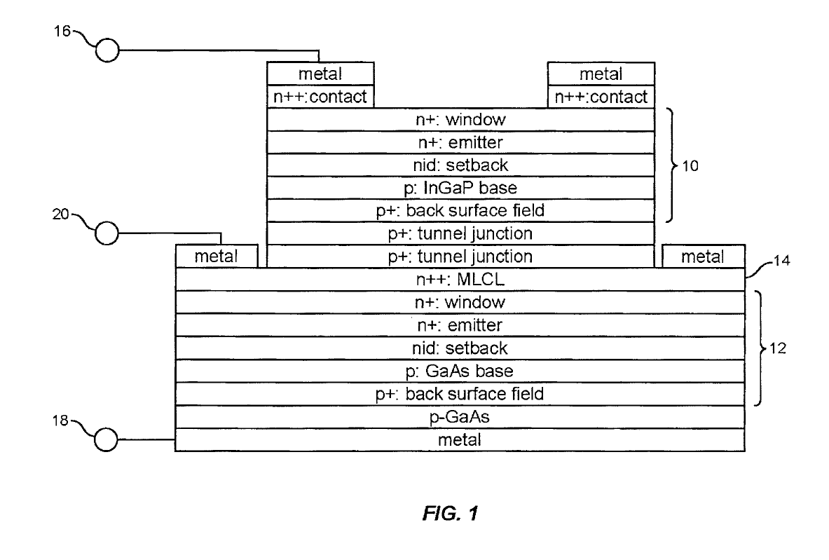

FIG. 1 illustrates a schematic of a multi-terminal dual junction solar cell. As shown therein, the multi-terminal solar cell is epitaxically grown on a GaAs substrate. The solar cell comprises a GaAs heterojunction subcell 12, a InGaP homojunction subcell 10 and a MLCL 14 disposed therebetween. The MLCL 14 has a higher band gap energy than that of the underlying bottom GaAs cell 12 to minimize absorption losses. The MLCL 14 also includes high conductivity to minimize series resistance losses and provide ohmic contact, the MLCL 14 is constructed of a high-quality crystalline material to minimize deleterious material effects to the InGaP cell 10. Examples of materials for the MLCL 14 include AlGaAs and InGaP. However, due to its high conductivity, InGaP is preferred. The InGaP MLCL 14 preferably has a band gap of 1.93 eV and the sheet resistance less than 10 ohm/sq.

As illustrated in FIG. 1, a first terminal 18 may be connected to a metal disposed on the back side of the GaAs substrate formed on the GaAs subcell 12. Likewise, a second terminal 16 may be connected to a metal layer disposed above the InGaP subcell 10. Further, in one embodiment, a third terminal 20 may be connected to a metal layer contacting the MLCL 14.

Each semiconductor subcell within the solar cell comprises several layers. For instance, both the InGaP subcell 10 and the GaAs subcell 12 include an n-type window layer, an n-type emitter layer, a non-intentionally doped set-back layer, and a p-type back surface field layer. Moreover, the InGaP subcell 10 includes an InGaP base layer and the GaAs subcell 12 includes a GaAs base layer. A tunnel junction comprising an n-type layer and a p-type layer is formed between the InGaP subcell 10 and MLCL 14 and provides ohmic contact therebetween.

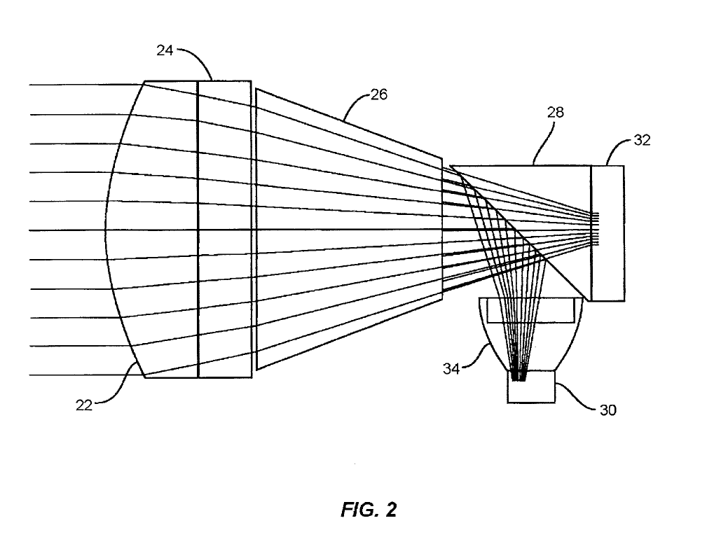

The above described solar cell may be used in conjunction with one or more other solar cells. Typically the hybrid optical concentrating system, illustrated in FIG. 2, is configured to convert light energy into electrical energy. As shown in FIG. 2, a lens 22 is positioned in front of a first solar cell 24, such as an InGaN solar cell. Generally, the first solar cell 24 converts the light energy into electrical energy. In one embodiment, the first solar cell converts light energy that is greater than 2.4 eV on the terrestrial spectrum. The remaining spectrum is concentrated by a first concentrator 26, such as a hollow pyramid concentrator, and directed to a prism 28 where the spectrum split in different directions. The prism 28 directs some of the light energy in a first direction toward a second solar cell 30 and directs some of the light energy in a second direction, generally orthogonal to the first direction, to a third solar cell 32. A second concentrator 34 concentrates the light energy directed from the prism 28 toward the second solar cell 30.

In one embodiment, the second solar cell 30 has an InGaP subcell 10 stacked on a GaAs subcell 12 and converts the light energy between 1.84 eV-1.43 eV. The third solar cell 32 based on silicon or GaInAsP cell stacked on a GaInAs cell converts the light energy below 1 eV.

In one embodiment of FIG. 2, concentrating system is configured for the first solar cell 24 to convert high energy photons, the second solar cell 30 to convert medium energy photons, and the third solar cell 32 to convert lower energy photons.

Table 1 illustrates the power generation of a two-terminal solar cell having a top InGaP subcell and a bottom GaAs subcell compared to a three-terminal solar cell having a top InGaP subcell 10, an InGaP MLCL 14, and a bottom GaAs subcell 12. A filter was applied to the two-terminal and three-terminal solar cells to simulate the presence of an InGaN solar cell mechanically stacked above the second solar cells. Various spectral conditions and top subcell band gaps were tested at approximately 13-sun AM1.5G concentration.

TABLE 1

| | Power Output | Power Output for | Power Output for | |
|---|---|---|---|---|
| | for a two- | the InGaP top | the GaAs bottom | Total Power |
| | terminal | subcell in a three- | subcell in a three- | Output for a |
| Tested Spectral | device | terminal device | terminal device | three-terminal |
| Conditions | (mW/cm²) | (mW/cm²) | (mW/cm²) | device (mW/cm²) |
| no filter | 371 | 218 | 163 | 381 |
| InGaP top subcell | | | | |
| band gap of 1.9 eV | | | | |
| 2.4 eV filter | 214 | 124 | 163 | 287 |
| InGaP top subcell | | | | |
| band gap of 1.9 eV | | | | |
| 2.6 eV filter | 276 | 160 | 163 | 323 |
| InGaP top subcell | | | | |
| band gap of 1.9 eV | | | | |
| 2.4 eV filter | 270 | 157 | 140 | 297 |
| InGaP top subcell | | | | |
| band gap of 1.84 eV | | | | |
| 2.6 eV filter | 329 | 194 | 141 | 335 |
| InGaP top subcell | | | | |
| band gap of 1.84 eV | | | | |

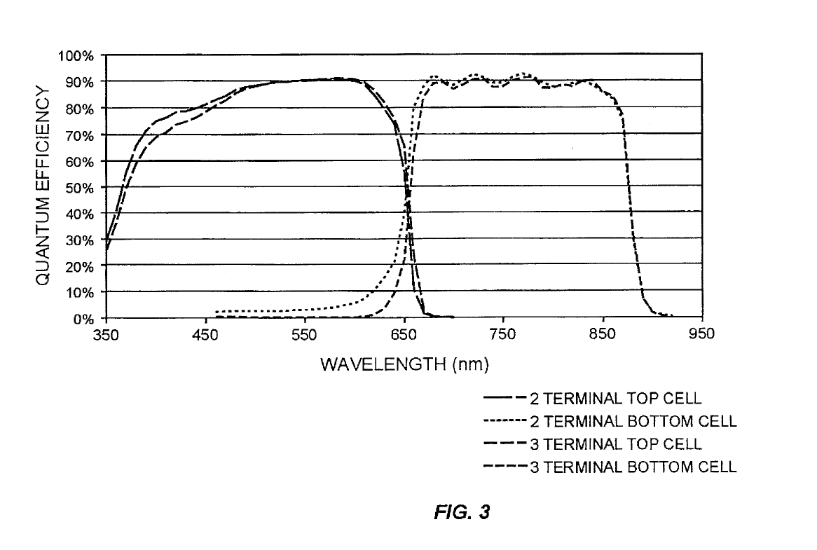

As shown in Table 1, two and three-terminal solar cell output power is nearly equal if the InGaP top subcell band gap is 1.9 eV for an unfiltered spectrum and 1.84 eV for a 2.6 eV filtered spectrum. Thus, the preferred band gap of the InGaP top subcell 10 in a three-terminal solar cell having a MLCL 14 is 1.84 eV when the three-terminal solar cell is used in conjunction with an InGaN solar cell. Similar testing, as shown in FIG. 3, indicates that the preferred band gap of the bottom subcell 10 in a three-terminal device having a MLCL 14 is 1.43 eV. Further, the preferred band gap of the filter, representing the band gap in the InGaN solar cell, is 2.6 eV.

The performance of the three-terminal solar cell is increased if the InGaN solar cell has a band gap of 2.4 eV and its output power exceeds 94 mW/cm² or if the InGaN solar cell has a band gap of 2.6 eV and its output power exceeds 58 mW/cm². Moreover, the power requirement for the InGaN cell is slightly relaxed if the band gap in the InGaP top subcell 10 is reduced to 1.84 eV. In this case, InGaN cell power is reduced by approximately 10 mW/cm² from the previous values. Thus, in a three-terminal device, an InGaP top subcell 10 band gap of 1.84 eV is preferred to reduce the power requirement for the InGaN solar cell and to relax the band gap in the top subcell 10.

FIG. 3 illustrates the quantum efficiency (QE) of a two-terminal solar cell compared to the QE's of the individual cells within the three-terminal solar cell for a 10 mm×10 mm active area. The structural parameters for the active layers in both configurations are identical. The QE of the InGaP top subcell in both device configurations is nearly identical between approximately 500 nm and approximately 700 nm. However, the InGaP top subcell 10 in the three-terminal device experienced a reduced QE with photon wavelengths below approximately 500 nm. This reduced spectral response is caused by absorption in the window layer. The QE of the GaAs bottom subcell in both device configurations is nearly identical between approximately 650 nm and approximately 900 nm. However, the GaAs bottom subcell 12 in the three-terminal device experienced a reduced QE with photon wavelengths below approximately 640 nm. This reduced spectral response is caused by absorption in the MLCL 14. These results lead to a ˜0.5 mA/cm² reduction in current in the three-terminal device compared to the two-terminal device.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The present invention may be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A solar cell comprising:
a GaAs first layer operatively connected with a first terminal and having a band gap of approximately 1.43 eV;
an InGaP second layer operatively connected with a second terminal and having a band gap of approximately 1.84 eV; and
a middle lateral conduction layer disposed between the GaAs first layer and the InGaP second layer, the middle lateral conduction layer having a band gap higher than the band gap of the GaAs first layer.

2. The solar cell of claim 1 wherein the middle lateral conduction layer is operatively connected with a third terminal.

3. The solar cell of claim 1 wherein the middle lateral conduction layer is comprised of InGaP.

4. The solar cell of claim 1 wherein the middle lateral conduction layer is comprised of AlGaAs.

5. The solar cell of claim 1 wherein the solar cell converts photons having an energy of between approximately 1.84 eV and approximately 1.43 eV and is spaced away from an InGaN solar cell that converts photons having an energy greater than approximately 2.4 eV.

6. The solar cell of claim 1 wherein the GaAs first layer is in a heterojunction configuration with the middle lateral conduction layer and the InGaP second layer is in a homojunction configuration with the middle lateral conduction layer.

7. A solar cell comprising:
a GaAs heterojunction subcell operatively connected with a first terminal and having a band gap of approximately 1.43 eV;
a InGaP homojunction subcell operatively connected with a second terminal and having a band gap of approximately 1.84 eV; and
a InGaP lateral conduction layer disposed between the GaAs subcell and the InGaP subcell and having a band gap of 1.93 eV and a sheet resistance of less than 10 ohm/sq, the InGaP lateral conduction layer operatively connected to a third terminal.

8. The solar cell of claim 7 wherein the solar cell converts photons having an energy of between approximately 1.84 eV and approximately 1.43 eV and is spaced away from an InGaN solar cell that converts photons having an energy greater than approximately 2.4 eV.

9. The solar cell of claim 8 wherein the InGaN solar cell converts photons having an energy of approximately 2.6 eV into electric energy and the InGaP subcell has an output power of approximately 194 mW/cm².

10. The solar cell of claim 7 wherein the quantum efficiency of the InGaP subcell is reduced, compared to the quantum efficiency of a two-terminal device having an InGaP subcell and a GaAs subcell, below approximately 500 nm.

11. The solar cell of claim 10 wherein the quantum efficiency of the GaAs subcell is reduced, compared to the quantum efficiency of the two-terminal device, below approximately 640 nm.

12. A photovoltaic solar cell arrangement comprising:
a InGaN solar cell for converting photons having an energy between approximately 2.4 eV and approximately 2.6 eV into electric energy;
a three terminal solar cell for receiving photons passing through the InGaN solar cell and converting the photons having an energy of between approximately 1.84 eV and approximately 1.43 eV into electric energy, the three-terminal solar cell comprising:
an InGaP layer associated with a first terminal and having a band gap of approximately 1.84 eV;
an InGaP lateral conduction layer disposed below the InGaP layer and having a band gap of 1.93 eV and a sheet resistance of less than 10 ohm/sq, the InGaP lateral conduction layer associated with a second terminal; and
a GaAs layer disposed below the InGaP lateral conduction layer and associated with a third terminal and having a band gap of approximately 1.43 eV.

13. The photovoltaic solar cell arrangement of claim 12 wherein the InGaN solar cell has an output power that exceeds approximately 58 mW/cm².

14. The photovoltaic solar cell arrangement of claim 13 wherein the InGaN solar cell has an output power that exceeds approximately 94 mW/cm².

15. The photovoltaic solar cell arrangement of claim 12 wherein the quantum efficiency of the InGaP layer in the three-terminal device is nearly identical to the quantum efficiency of a two-terminal device having a InGaP layer and the GaAs layer, in the range of approximately 500 nm and approximately 700 nm.

16. The photovoltaic solar cell arrangement of claim 12 wherein the quantum efficiency of the GaAs layer in the three-terminal device is nearly identical to the quantum efficiency of the two-terminal device, in the range of approximately 650 nm and approximately 900 nm.

17. The photovoltaic solar cell arrangement of claim 16 wherein the quantum efficiency of the GaAs layer in the three-terminal device is reduced compared to the quantum efficiency of the two-terminal device, below approximately 640 nm.

18. The photovoltaic solar cell arrangement of claim 17 wherein the reduced quantum efficiency of the GaAs layer is caused by absorption in the MLCL.

19. A photovoltaic solar cell arrangement comprising:
a first solar cell for converting light energy into electrical energy;
a prism for receiving the light energy passing through the first solar cell, the prism being positioned to direct some of the light energy in a first direction toward a second solar cell and to direct some of the light energy in a second direction, generally orthogonal to the first direction, toward a third solar cell, each of the second and third solar cells configured to convert the light energy into electrical energy;
the second solar cell comprising:
a first InGaP layer;
a second InGaP layer disposed below the first InGaP layer; and
a GaAs layer disposed below the second InGaP layer.

20. The photovoltaic solar cell arrangement of claim 19 further comprising:
a first optical concentrator disposed between the first solar cell and the prism for concentrating the light energy passing through the first solar cell; and
a second optical concentrator disposed between the prism and the second solar cell for concentrating the light energy directed from the prism toward the second solar cell.
